(19) United States
(12) Patent Application Publication
(10) Pub. No.: US 2014/0374467 A1
(43) Pub. Date: Dec. 25, 2014

(54) CAPILLARY BONDING TOOL AND METHOD OF FORMING WIRE BONDS

(71) Applicants: Jia Lin Yap, Klang (MY); Yin Kheng Au, Petaling Jaya (MY); Lai Cheng Law, Cheras (MY)

(72) Inventors: Jia Lin Yap, Klang (MY); Yin Kheng Au, Petaling Jaya (MY); Lai Cheng Law, Cheras (MY)

(21) Appl. No.: 13/924,625

(22) Filed: Jun. 24, 2013

(51) Int. Cl. H01L 23/00; B23K 20/26

(52) U.S. Cl. CPC H01L 24/78; B23K 20/26; H01L 24/43; H01L 2224/431; H01L 2924/01029; H01L 2924/37001
USPC 228/180.5; 228/33

(57) ABSTRACT

A capillary bonding tool for wire bonding includes a first section, a second section and a bonding section. The first section has a first outer peripheral sidewall, an opposing first inner sidewall that extends generally parallel to the central longitudinal axis, and a first opening surrounded by the first inner sidewall. The second section has a second outer peripheral sidewall, an opposing second inner sidewall that extends at an angle with respect to the central longitudinal axis, and a second tapered opening surrounded by the second inner sidewall. The bonding section has a peripheral ridge extending axially outwardly from the second inner sidewall of the second section. The peripheral ridge has a third outer peripheral sidewall, a third inner tubular sidewall that extends generally parallel to the central longitudinal axis and radially outwardly of the first inner sidewall, and a third opening surrounded by the third inner tubular sidewall.

### BACKGROUND OF THE INVENTION

The present invention is directed to semiconductor device assembly and, more particularly, to an improved method of wire bonding electrical contacts and a capillary therefor.

Typically, gold has been used for wire bonding electrical contacts. However, due to the constantly increasing price of gold, copper has become a popular alternative to gold for bond wires. In addition to being less expensive than gold, copper exhibits higher thermal and electrical conductivity, resulting in more thermally tolerant bonds. Copper also has a greater mechanical strength than gold. Thus, a recent trend has been to apply copper bond wire using a conventional wire bonder.

A capillary 10 of a conventional wire bonder is shown in FIGS. 1-2. The capillary 10 includes a body 12 having a first section 14 including a wire bore 16 and a second section 18 including a chamfer 20. The second section 18 is downstream of the first section 14 in terms of the direction of feed of a bond wire 24 (see FIG. 3). Thus, as the bond wire 24 passes through the wire bonder 10, the bond wire 24 passes through the bore 16 of the first section 14 toward the chamfer 20 of the second section 18.

The second section 18 is a wire bonding tip. A distal end surface 22 of the bonding tip is a working or bonding surface. The bonding surface 22 is in the form of an annular, generally planar surface. The chamfer 20 is a recess or aperture formed in the bonding surface 22. The chamfer 20 has a larger diameter D₂₀ than a diameter D₁₆ of the bore 16. The diameter of the bonding tip 18 is equivalent to the diameter D₂₂ of the bonding surface 22.

As shown in FIG. 3, for the formation of a ball bond using the wire bonder, the bond wire 24 is passed through the wire bore 16 toward the chamfer 18. As one end of the bond wire 24 reaches the chamfer 20, a free air ball (FAB) 26 is formed by heating the end of the wire 24 in the area of the chamfer 20 with a hydrogen flame or a spark. The resulting FAB 26 projects from the bonding surface 22 of the capillary 10 outside of the chamfer 20. Then, the FAB 26 is pressed against the surface of a bond pad 28 by the capillary 10 to form a ball bond.

However, when copper wire is applied using a conventional wire bonder, certain drawbacks exist. For example, because copper has a relatively high stiffness or hardness, more force and energy (i.e., higher ultrasonic power) must be used during the bonding process to create the bonds. The use of higher force, in turn, can lead to bond pad damage and potentially reduced reliability.

Further, for the formation of ball bonds on aluminum pads, the use of a higher bonding force can lead to cratering and aluminum splash-out. That is, the process of pressing the ball onto the surface of the bond pad, while vibrating, causes displacement or splash out of the aluminum (generally the top aluminum layer) on the bond pad beyond the ball footprint and potentially beyond the edges of the pad. Such an aluminum splash-out 30 is shown in FIG. 3. This leaves less aluminum on which the copper wire can bond. Also, as a result of the aluminum splash-out, a gap may form between the aluminium splash-out and the copper ball bond, which can cause galvanic corrosion when moisture is present in the encapsulating mold compound. Aluminum splash-out also puts more stress on the underlying dielectric or passivation layer, which can lead to cratering.

In addition, the capillary 10 has a relatively large diameter bonding tip 18, which may cause short tail defects and damage the bond pad area during formation of bonds.

Specific drawbacks also exist when using such conventional capillaries to form ball bonds on fine pitch devices. In particular, as shown in FIG. 3, in conventional capillaries, the FAB 26 projects outside of the body 12 of the capillary 10 upon formation. As such, it is difficult to control placement and positioning of a bonded ball using conventional capillaries. For the same reason, it is also difficult to ensure uniform shapes and dimensions (e.g., thickness and diameter) of the bonded balls using conventional capillaries.

Referring to FIG. 4, it is also problematic to form a strong stand-off-stitch bond (SSB) 32 using conventional capillaries, because the interface or bonding contact area of the bonding tip 18 and the stitch bond 32 has a limited surface area. As a result of this limited contact area, the strength and reliability of the resulting stitch bond is negatively impacted.

It is therefore desirable to provide an improved wire bonding capillary tool and wire bonding method that will minimize damage to electrical contacts and improve control of the resulting wire bonds.

### BRIEF DESCRIPTION OF THE DRAWINGS

The present invention is illustrated by way of example and is not limited by embodiments thereof shown in the accompanying figures, in which like references indicate similar elements. Elements in the figures are illustrated for simplicity and clarity and have not necessarily been drawn to scale. Notably, certain dimensions have been exaggerated for clarity.

In the drawings:

FIG. 1 is a side cross-sectional elevational view of a conventional capillary wire bonding tool;

FIG. 2 is a bottom plan view of the conventional capillary wire bonding tool of FIG. 1;

FIG. 3 is an enlarged side cross-sectional elevational view of the conventional capillary wire bonding tool of FIG. 1 in use for forming a ball bond;

FIG. 4 is a side cross-sectional elevational view of a portion of the conventional capillary wire bonding tool of FIG. 1 in use for forming a stand-off stitch bond;

FIG. 5 is a schematic block diagram illustrating the configuration of a wire bonder in accordance with an embodiment of the present invention;

FIG. 6 is a side cross-sectional elevational view of a capillary wire bonding tool in accordance with an embodiment of the invention;

FIG. 7 is a bottom plan view of the capillary wire bonding tool of FIG. 6;

FIG. 8 is an enlarged side cross-sectional elevational view of the capillary bonding tool of FIG. 6 in use for forming a ball bond;

FIG. 9 is a side cross-sectional elevational view of an electrical connection in accordance with an embodiment of the present invention; and

FIG. 10 is a side cross-sectional elevational view of a portion of the capillary wire bonding tool of FIG. 6 in use for forming a stand-off stitch bond.

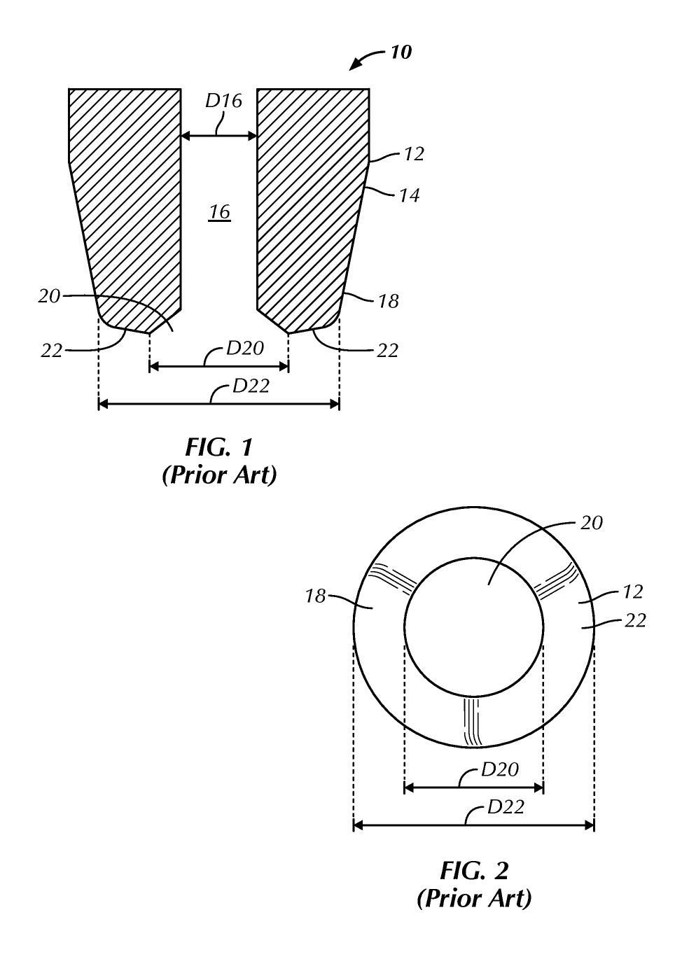

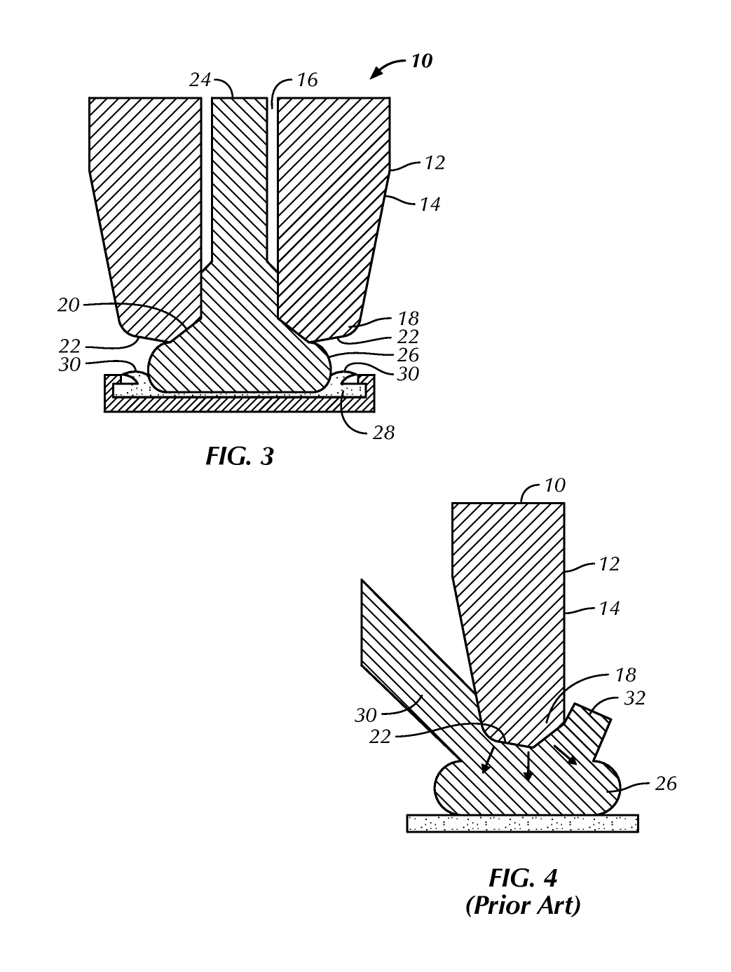

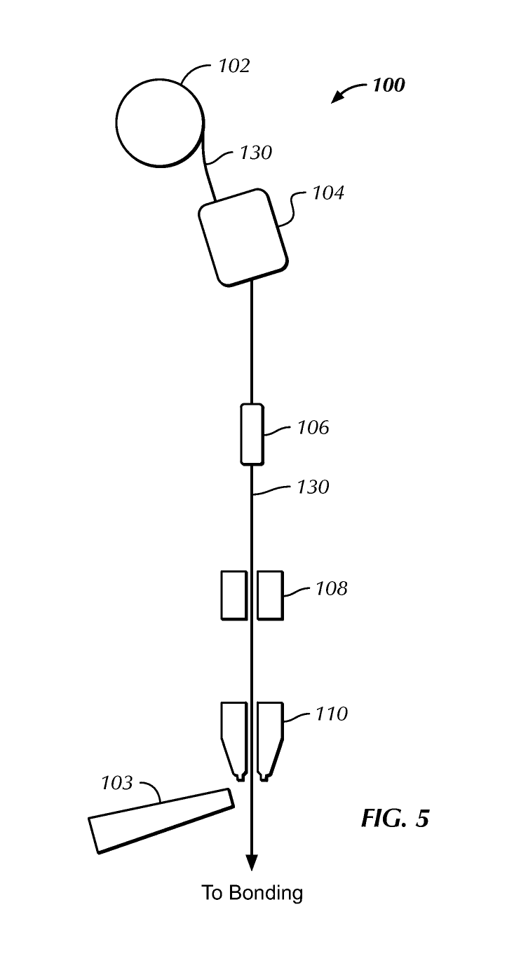

### DETAILED DESCRIPTION OF THE INVENTION

Referring to the drawings, wherein the same reference numerals are used to designate the same components throughout the several figures, there is shown in FIG. 5 a schematic block diagram of a wire bonder 100 used for making an electrical interconnection in accordance with a preferred embodiment of the invention.

Referring to FIG. 5, the wire bonder 100 includes a bond wire feed 102, and more particularly a spool 102 of bond wire 130, an air guide 104, a wire tensioner 106, a wire clamp 108, an EFO device 103 and a capillary 110. The bond wire 130 may be removably inserted through the capillary 110 for the formation of a ball, specifically a free air ball, at an end of the bond wire 130 by the EFO device 103.

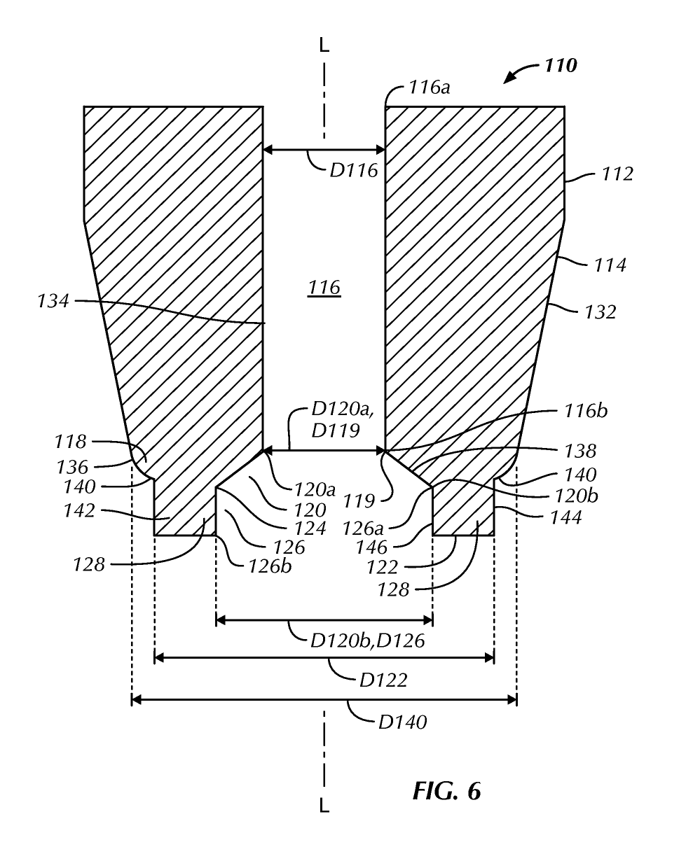

Referring to FIG. 6, the capillary 110 includes a body 112 having a generally tapered or frustoconical shape and a central longitudinal axis L. However, it will be understood that the capillary body 112 may have an alternative shape, such as a conical or cylindrical shape. The body 112 comprises a first section 114 including a first outer peripheral sidewall 132, a first inner sidewall 134 and a first opening 116 surrounded by the first inner sidewall 134. The first opening 116 is preferably a bore 116 through which the bond wire 130 may pass.

The first outer peripheral sidewall 132 of the first section 114 preferably has a generally tapered or frustoconical shape. However, it will be understood that the first outer peripheral sidewall 132 may have an alternative shape, such as conical or cylindrical. The first inner sidewall 134 preferably extends generally parallel to the central longitudinal axis L.

The wire bore 116 extends generally along and through a geometric center of the first section 114 of the capillary body 112. The bore 116 has a first end 116a and an opposing second end 116b which is downstream of the first end 116a. The bore 116 has a generally cylindrical shape when viewed from above, and thus the first inner sidewall 134 surrounding the bore 116 has a generally cylindrical shape as well. The bore 116 also has a generally uniform or constant diameter D₁₁₆ between the first end and second ends 116a, 116b. The second end 116b of the bore 116 is a point of transition 119 between the first section 114 of the capillary body 112 and a second section 118 of the capillary body 112. The first transition point 119 has a diameter D₁₁₉ equal to the diameter D₁₁₆ of the bore 116 of the first section 114.

The second section 118 includes a second outer peripheral sidewall 136, a second inner sidewall 138 and a second opening 120 surrounded by the second inner sidewall 138. The second inner sidewall 138 preferably extends at an angle with respect to the central longitudinal axis, such that the second opening 120 is preferably a generally sloped or angled opening 120. More preferably, the opening 120 is a tapered opening 120 formed in a geometric center of the second section 118. The first transition point 119 marks the point of transition between the bore 116 of the first section 114 and the second opening 120 of the second section 118.

The second opening 120 preferably has a generally sloped or tapered shape, and thus has a varying diameter. In a preferred embodiment, the second opening 120 is in the form of a chamfer. More particularly, the chamfer 120 has an open first end 120a corresponding to the first transition point 119 and an opposing open second end 120b corresponding to an outlet of the wire bonder 100. In a preferred embodiment, the second section 118 includes a distal end surface 140 that extends generally radially from the second outer peripheral sidewall 136 toward the second inner sidewall 138.

In a preferred embodiment, the chamfer 120 has a first diameter D₁₂₀ₐ at the first end 120a, which is generally equal to the diameter D₁₁₉ of the transition point 119, and a second diameter D_{120b} at the second end 120b which is at least slightly larger than the first diameter D₁₂₀ₐ. Thus, the chamfer 120 flares at least slightly outwardly as it extends from the transition point 119 and the first end 120a toward the second end 120b. The distal end surface 140 is formed at the second end 120b of the chamfer 120.

The second section 118 of the capillary body 112 is located downstream of the first section 114 in terms of the direction of feed of the bond wire 130. Thus, as it is fed through the wire bonder 100, the bond wire 130 passes through the bore 116 of the first section 114 toward the chamfer 120 of the second section 118.

The capillary 110 further includes a third section 142 in the form of a bonding section or tip. The bonding tip 142 includes a peripheral ridge or flange 128 which projects distally and outwardly away from the second end 120b of the chamfer 120, specifically from the second inner sidewall 138. More particularly, the peripheral ridge 128 projects axially outwardly away from the distal end surface 140 of the second section 118. Preferably, the projecting ridge 128 extends generally perpendicularly (i.e., 90°) away from the distal end surface 140 of the second section 118 toward the substrate to which the wire is to be bonded.

The peripheral ridge 128 includes a third outer peripheral sidewall 144, a third inner sidewall 146, and a third opening 126 surrounded by the third inner sidewall 146. The third inner sidewall 146 preferably extends generally parallel to the central longitudinal axis L. Also, the third inner sidewall 146 extends generally radially outwardly of the first inner sidewall 134. The third opening 126 has a first open end 126a and an opposing second open end 126b which is downstream of the first end 126a. The third opening 126 has a generally cylindrical shape when viewed from above, and thus the third inner sidewall 146 surrounding the third opening 126 has a generally cylindrical shape as well. The third opening 126 also has a generally uniform or constant diameter D₁₂₆ between the first end 126a and the second end 126b.

The third opening 126 is located downstream of the chamfer 120, such that the second end 120b of the chamfer 120 is a point of transition 124 between the second section of the capillary body 112 and the bonding tip 142. The second transition point 124 has a diameter equal to the diameter D₁₂₆ of the third opening 126 of the bonding tip 142 and the diameter D_{120b} of the second end 120b of the chamfer 120.

In a preferred embodiment, the third opening 126 is a ball containment recess 126 and a distal end face 122 of the projecting ridge 128 is a bonding surface. More preferably, the distal end face 122 is a generally flat bonding tip. Thus, the bonding surface 122 of the capillary 110 is preferably in the form of an annular, generally planar surface surrounding the ball containment recess 126. The second open end 126b of the ball containment recess 126 is generally aligned with the bonding surface 122.

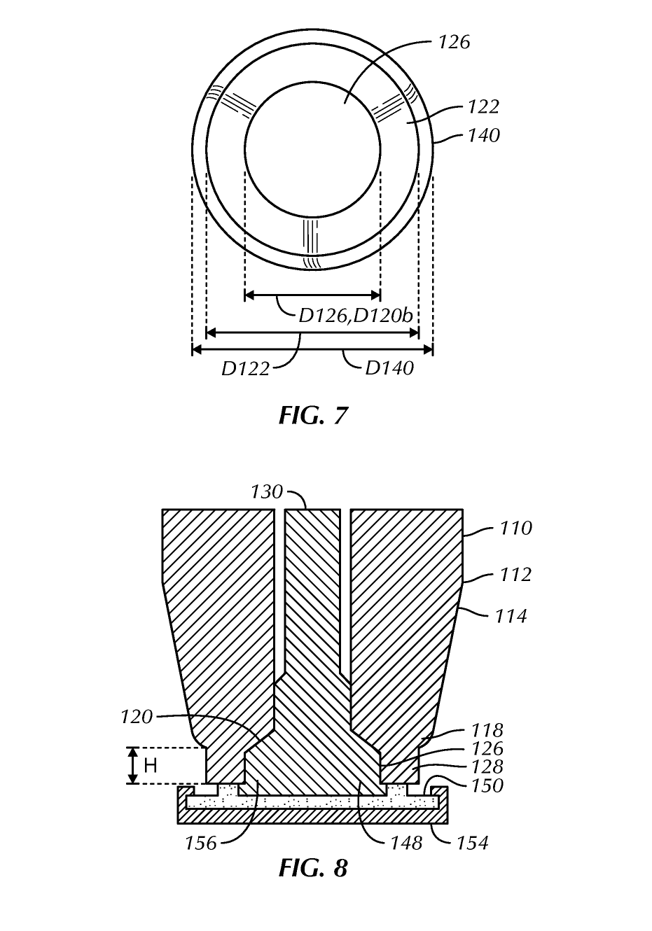

The chamfer 120, and more particularly the distal end surface 140 of the second section 118, is spaced apart from the bonding surface 122 of the bonding tip 142. The distal end surface 140 is preferably a generally horizontally extending ledge positioned between the second outer peripheral sidewall and the third outer peripheral sidewall, the second outer peripheral sidewall being positioned radially outwardly from the third outer peripheral sidewall. In addition, as shown in FIGS. 6-7, the diameter D₁₂₂ of the bonding surface 122 is preferably at least slightly smaller than the diameter D₁₄₀ of the distal end surface 140 of the second section 118.

Thus, the capillary bonding tip 142, and particularly the bonding surface 122, of the capillary 110 has a relatively smaller diameter D₁₂₂ than the bonding surface diameter of conventional capillary bonding tools. As a result of this smaller bonding surface diameter, the capillary 110 is less likely to cause short tail defects and damage to the bond pad area during formation of bonds.

In an exemplary embodiment, the bond wire 130 is made from copper, although other conductive materials may be used as well. At least a portion of the bond wire 130 may also include an insulating coating (not shown), which can be an insulating organic or polymeric material surrounding at least a portion of the conductive core.

In a preferred embodiment, as shown in FIG. 8, the wire bonder 100 is used to bond the wire 130 to a first electrical contact 150. The first bond 156 at the first electrical contact 150 is preferably a ball bond 156. The first electrical contact 150 is preferably provided on a substrate 154 or some other form of support. As shown in the example of FIG. 8, the first electrical contact 150 may be in the form of a bond pad on the substrate 154. The bond pad 150 is preferably made from aluminum (Al), although other conductive materials may be used as well. The bond pad 150 may also be coated, alloyed or pre-plated with a metal layer or layers such as gold (Au), nickel (Ni), palladium (PD), tin (Sn) or the like.

Referring to FIG. 8, for the formation of the ball bond 156, the copper bond wire 130 is passed through the wire bore 116 toward the chamfer 120. As one end of the wire 130 reaches the chamfer 120, a free air ball (FAB) 148 is formed by heating the end of the wire 130 in the chamfer 120 with a hydrogen flame or a spark. Then, the FAB 148 is pressed against the surface of the bond pad 150 by the capillary 110 and thermocompression, thermosonic or ultrasonic wire bonding is performed to bond the end of the bond wire 130 to the first bond pad 150. However, it will be understood that other conventional methods of forming the first bond 156 may also be used.

As shown in FIG. 8, upon formation, the FAB 148 remains contained within the body 112 of the capillary 110, and more particularly within the chamfer 120 and the ball containment recess 126 of the bonding tip 142. As a result, placement and positioning of the FAB 148, as well as the resulting bonded ball, can be easily and effectively controlled. Also, because the FAB 148 remains contained with the capillary body 112 upon and during formation, one can consistently form FABs of uniform shapes and dimensions without splash-out or other defects. Also, it will be understood that the height H of the peripheral ridge 128 may be increased or decreased as necessary to obtain a free air ball of the desired dimensions (e.g., a free air ball of a desired height or thickness).

Since the bond wire 130 is a copper wire, a generally higher force is required for formation of the ball bond on the aluminum bond pad 150. However, due to the configuration of the capillary 110, and more particularly due to the projecting peripheral ridge 128, no aluminum splash-out occurs as the distal end surface 122 of the peripheral ridge 128 flattens out any aluminum that may be displaced. As a result, the copper ball is well bonded to the aluminum bond pad 150, with virtually no gap therebetween, such that the likelihood of galvanic corrosion and cratering is reduced, if not prevented.

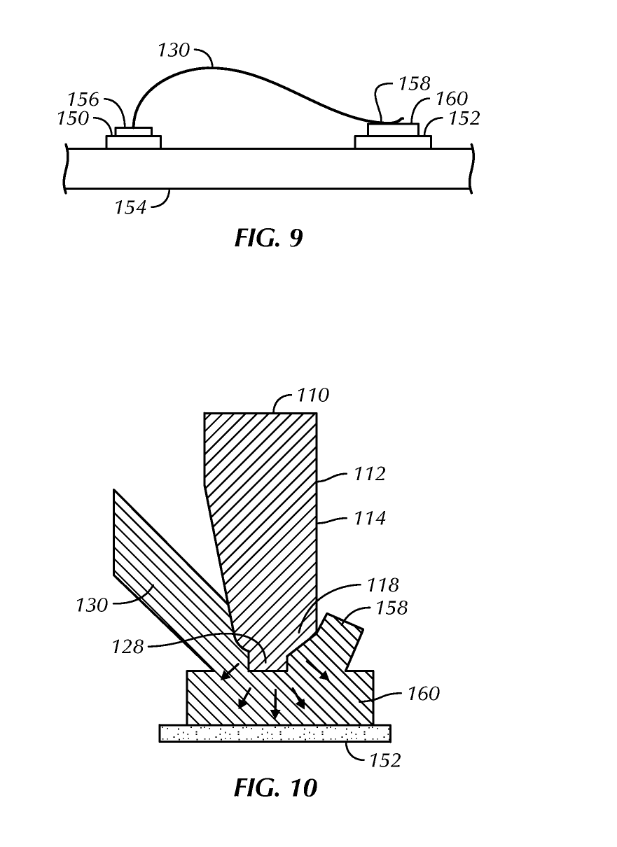

In an exemplary embodiment, the capillary 110 is used to connect the first electrical contact 150 to a second electrical contact 152 with the bond wire 130, as shown in FIG. 9. The first bond 156 at the first electrical contact 150 is preferably a ball bond 156, as described above, and the second bond 158 at the second electrical contact 152 is preferably a stand-off-stitch bond 158.

The second electrical contact 152 may located on the same substrate 154 as the first electrical contact 150, as shown in FIG. 9, or the two contacts 150, 152 may alternatively be disposed on different substrates 154 or supports. The second electrical contact 152 is preferably in the form of a conventional lead, for a semiconductor package or the like, and may be made of aluminum (Al). The second electrical contact 152 may also be coated, alloyed or pre-plated with a metal layer or layers such as gold (Au), nickel (Ni), palladium (PD), tin (Sn) or the like. It will also be appreciated that other like conductive materials may be used to form the second electrical contact 152.

First, the capillary 110 is used to form an electrically conductive bump 160, known as a stud bump 160, on the surface of the second electrical contact 152. Preferably, the stud bump 160 is in the form of a flat-topped bump due to the configuration of the bonding section 118 of the capillary 110.

Next, the first ball bond 156 is formed on the first electrical contact 150, as described above, to bond a first end of the wire 130 to the first electrical contact 150. Then, the capillary 110 is used to form the second bond 158 (i.e., a stitch bond) at the second electrical contact 152. The stitch bond 158 may be formed by using the capillary 110 to press the second end of the bond wire 130 against the stud bump 160 formed on the second electrical contact 152; performing thermocompression, thermosonic or ultrasonic wirebonding to bond the metal of the bond wire 130 to the stud bump 160; and finally lifting the capillary 110 off of the stud bump 160 to break the bond wire 130.

As shown in FIG. 10, due to the configuration of the bonding tip 142, and particularly due to the projecting peripheral ridge 128, there is a large bonding contact area between the bonding tip 142 and the stitch bond 158. As a result of this large contact area, the strength and reliability of the resulting stitch bond is increased.

In the foregoing specification, the invention has been described with reference to specific examples of embodiments of the invention. It will, however, be evident that various modifications and changes may be made therein without departing from the broader spirit and scope of the invention as set forth in the appended claims.

Those skilled in the art will recognize that boundaries between the above-described operations are merely illustrative. The multiple operations may be combined into a single operation, a single operation may be distributed in additional operations and operations may be executed at least partially overlapping in time. Further, alternative embodiments may include multiple instances of a particular operation, and the order of operations may be altered in various other embodiments.

The terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

In the claims, the word ‘comprising’ or ‘having’ does not exclude the presence of other elements or steps then those listed in a claim. Further, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The fact that certain measures are recited in mutually different claims does not indicate that a combination of these measures cannot be used to advantage.

1. A capillary bonding tool for making wire bonds, the capillary bonding tool comprising:
a central longitudinal axis;
a first section having a first outer peripheral sidewall, an opposing first inner sidewall which extends generally parallel to the central longitudinal axis, and a first opening surrounded by the first inner sidewall;
a second section having a second outer peripheral sidewall, an opposing second inner sidewall which extends at an angle with respect to the central longitudinal axis, and a second tapered opening surrounded by the second inner sidewall; and
a bonding section having a peripheral ridge extending axially outwardly from the second inner sidewall of the second section, the peripheral ridge having a third outer peripheral sidewall, a third inner tubular sidewall which extends generally parallel to the central longitudinal axis and radially outwardly of the first inner sidewall, and a third opening surrounded by the third inner tubular sidewall.

2. The capillary bonding tool of claim 1, wherein the second outer peripheral sidewall is positioned radially outwardly from the third outer peripheral sidewall and a generally horizontally extending ledge is positioned between the second outer peripheral sidewall and the third outer peripheral sidewall.

3. The capillary bonding tool of claim 1, wherein the second section has a first distal end surface extending from the second outer peripheral sidewall toward the second inner sidewall and the peripheral ridge has a second distal end surface extending from the third outer peripheral sidewall to the third inner sidewall, an outer diameter of the second distal end surface being smaller than an outer diameter of the first distal end surface.

4. The capillary bonding tool of claim 3, wherein the second distal end surface is a generally flat distal tip of the capillary bonding tool.

5. The capillary bonding tool of claim 1, wherein the second opening has a first end and a second end, a diameter of the second end being larger than a diameter of the first end.

6. The capillary bonding tool of claim 5, wherein the diameter of the first end of the second opening is generally equal to a diameter of the first opening.

7. The capillary bonding tool of claim 5, wherein the diameter of the second end of the second opening is generally equal to a diameter of the third opening.

8. The capillary bonding tool of claim 1, wherein a diameter of the third opening is essentially constant along the central longitudinal axis.

9. The capillary bonding tool of claim 1, wherein the first opening has a cylindrical shape.

10. The capillary bonding tool of claim 1, wherein the second tapered opening is in the form of a chamfer.

11. The capillary bonding tool of claim 1, wherein the third opening has a cylindrical shape.

12. A method of making a ball bond, the method comprising:
passing a bond wire through a wire bonding system, the wire bonding system having a bonding capillary, the bonding capillary having a body and a peripheral ridge axially extending outwardly from the body, the peripheral ridge having a distal end surface and a ball containment recess formed in the distal end surface;
forming a ball by heating a first end of the bond wire positioned in the ball containment recess, such that the formed ball is fully contained within the ball containment recess; and
bonding the formed ball to an electrical contact.

13. The method of claim 12, wherein the distal end face of the peripheral ridge is a bonding surface.

14. The method of claim 12, wherein the ball containment recess has a cylindrical shape.

15. The method of claim 12, wherein the peripheral ridge extends generally perpendicularly away from the body toward the electrical contact.
